(19) United States
(12) Patent Application Publication
(10) Pub. No.: US 2026/0353993 A1
(43) Pub. Date: Nov. 5, 2026

(54) Light Emitting Display Device

(71) Applicant: LG Display Co., Ltd., Seoul (KR)

(72) Inventors: Eunyoung Choi, Paju-si (KR); SangHun Han, Paju-si (KR); Dongmyung Lee, Paju-si (KR)

(21) Appl. No.: 19/635,297

(22) Filed: Mar. 31, 2026

(30) Foreign Application Priority Data
Apr. 30, 2025 (KR) 10-2025-0057518

(51) Int. Cl. H10K 59/80; H10K 59/122; H10K 59/35

(52) U.S. Cl. CPC H10K 59/8792; H10K 59/122; H10K 59/353

(57) ABSTRACT

A light emitting display device according to the present disclosure comprises: a plurality of pixels on a substrate; a driving element layer on the substrate; a pixel electrode disposed in each of the pixel on the driving element layer; a dummy pixel electrode disposed at least one side of the pixel electrode; a bank defining an emission area at the pixel electrode and a dummy emission area at the dummy pixel electrode; an emission layer continuously deposited on the pixel electrode, the dummy pixel electrode and the bank; a common electrode on the emission layer; and a light shielding layer overlapping the dummy pixel electrode except the pixel electrode. The pixel electrode and the dummy pixel electrode is connected to a driving element disposed in the driving element layer.

### CROSS-REFERENCE TO RELATED APPLICATIONS

This application claims the benefit of Republic of Korea Patent Application No. 10-2025-0057518 filed on Apr. 30, 2025, which is hereby incorporated by reference as if fully set forth herein.

### BACKGROUND

### Field of the Invention

The present disclosure relates to a light emitting display device.

### Discussion of the Related Art

A light emitting display device, which is a self-luminous display device, may have a structure in which a plurality of pixel areas equipped with light emitting diodes are arranged. As the pixel density increases, the distance between pixels becomes closer. Additionally, with the same resolution, the distance between the light emitting areas becomes closer as the light emitting area increases to improve brightness (or luminance). Under this condition, when a common functional layer is deposited as a single layer across all pixels, a lateral leakage current may occur between neighboring pixels in the horizontal direction.

When lateral leakage current occurs, unintended pixels may operate, making it difficult to display normal colors, which may result in a problem of deterioration in image quality. Various methods have been proposed to prevent lateral leakage current.

However, in the related arts for preventing lateral leakage current, a problem may occur in voltage compensation at a specific color pixel. The luminance expressed on the display device may be represented by dividing it into 256 gray levels between perfect black and perfect white. In one 8-bit grayscale example, the perfect black(or true black) may have a gray scale value of 255, and the perfect white (or true white) may have a grayscale value of 0. In one 16-bit grayscale example, the perfect black may have a grayscale value of 65536, and the perfect white may have a grayscale value of 0.

In a situation where a specific pixel is displayed in a perfect black and then it is changed to a gray scale-color, or a specific pixel is displayed in a gray scale-color and then it is changed to a perfect white, the color expression may not be performed to display correct grayscale value. Therefore, rather than simply eliminating the lateral leakage current, a more efficient way to control the lateral leakage current is needed. For example, it is necessary to develop a structure for an ultra-high resolution light emitting display device that may eliminate the lateral leakage current, or may intentionally provide compensation current depending on the driving conditions of the display device.

### SUMMARY

The purpose of the present disclosure, as for solving the problems described above, is to provide a bottom emission type light emitting display device having a structure capable of compensating driving current so as to implement the best image quality in any condition according to the grayscale of an image displayed on a display device. Another purpose of the present disclosure is to provide a bottom emission type light emitting display device that solves the problem of white pixels that should be displayed in low-grayscale being displayed in high-grayscale due to the lateral leakage current.

In order to accomplish the above-mentioned purposes of the present disclosure, a light emitting display device according to the present disclosure comprises: a plurality of pixels on a substrate; a driving element layer on the substrate; a pixel electrode disposed in each of the pixels on the driving element layer; a dummy pixel electrode disposed at least one side of the pixel electrode; a bank defining an emission area at the pixel electrode and a dummy emission area at the dummy pixel electrode; an emission layer continuously deposited on the pixel electrode, the dummy pixel electrode and the bank; a common electrode on the emission layer; and a light shielding layer overlapping the dummy pixel electrode except the pixel electrode. The pixel electrode and the dummy pixel electrode is connected to a driving element disposed in the driving element layer.

In an example, the light emitting display device further comprises: a color filter disposed between the driving element layer and the pixel electrode; and a planarization layer between the color filter and the pixel electrode. The light shielding layer is disposed between the substrate and the driving element layer.

In an example, the driving element layer includes: a data line; a driving current line parallel to the data line; a scan line intersecting the data line and the driving current line; a switching thin film transistor between the data line and the scan line; and a driving thin film transistor between the switching thin film transistor and the driving current line. The pixel electrode is connected to the driving thin film transistor. The dummy pixel electrode is connected any one of the data line, the switching thin film transistor and the driving thin film transistor. A compensation light emitting diode is disposed as corresponding to the light shielding layer.

In an example, the dummy pixel electrode is separated from the pixel electrode, and connected to a source electrode of the switching thin film transistor. The bank covers circumferences of the pixel electrode and the dummy pixel electrode.

In an example, the dummy pixel electrode is disposed at the dummy emission area by extended from the pixel electrode. The bank covers circumferences of the pixel electrode and the dummy pixel electrode, and is disposed between the pixel electrode and the dummy pixel electrode.

In an example, the plurality of pixels includes a blue pixel, a white pixel and a red pixel consequently arrayed. The dummy pixel electrode of the white pixel includes: a first dummy pixel electrode disposed at a first dummy emission area between the white pixel and the blue pixel; and a second dummy pixel electrode disposed at a second dummy emission area between the white pixel and the red pixel.

In an example, the driving element layer includes: a data line, a driving current line parallel to the data line and a scan line crossing to the data line and the driving current line in each of the pixels; a switching thin film transistor between the data lien and the scan line; and a driving thin film transistor between the switching thin film transistor and the driving current line. The pixel electrode of the white pixel is connected to the driving thin film transistor. The first dummy pixel electrode and the second dummy pixel electrode of the white pixel is connected to any one of the data line, the switching thin film transistor and the driving thin film transistor.

In an example, the first dummy pixel electrode is located in the first dummy emission area and connected to any one of the data line and the switching thin film transistor. The second dummy pixel electrode is extended from the pixel electrode to the second dummy emission area. The bank covers circumferences of the pixel electrode, the first dummy pixel electrode and the second dummy pixel electrode in the white pixel and is disposed between the pixel electrode and the second dummy pixel electrode of the white pixel.

In an example, the first dummy pixel electrode is extended from the pixel electrode to the first dummy emission area. The second dummy pixel electrode is extended from the pixel electrode to the second dummy emission area. The bank covers circumferences of the pixel electrode, the first dummy pixel electrode and the second dummy pixel electrode, and is disposed between the pixel electrode and the first dummy pixel electrode and between the pixel electrode and the second dummy pixel electrode.

In an example, the emission layer includes: a first emission layer on the pixel electrode, the dummy pixel electrode and the bank; a first charge generation layer on the first emission layer; a second emission layer on the first charge generation layer; a second charge generation layer on the second emission layer; a third emission layer on the second charge generation layer; a third charge generation layer on the third emission layer; and a fourth emission layer on the third charge generation layer.

In an example, the pixel electrode includes: a hole functional layer on the pixel electrode, the dummy pixel electrode and the bank and under the first emission layer; and an electron functional layer between the fourth emission layer and the common electrode.

In an example, the first emission layer provides a red light. The second emission layer provides a first blue light. The third emission layer provides a green light. The fourth emission layer provides a second blue light.

In an example, the emission area is a first region where lights provided from the emission layer emit to outside through the substrate. The dummy emission area is a second region where lights provided from the emission layer is blocked by the light shielding layer not to emit to outside.

The light emitting display device according to the present disclosure may have a compensation light emitting diode arranged on at least one side of a white pixel that may emit light by lateral leakage current. Therefore, the white pixel may not properly change the grayscale due to the lateral leakage current. Further, the compensation light emitting diode may be disposed in a non-emission area where the light shielding layer is located, so that the light emission condition may not be exposed to outside. Accordingly, it may provide high-quality images without distortion of image information due to the light emission condition of the compensation light emitting diode.

In addition to the effects of the present disclosure mentioned above, other features and advantages of the present disclosure are described below, or may be clearly understood by those skilled in the art from such descriptions and explanations.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view illustrating a schematic structure of a light emitting display device according to an embodiment of the present disclosure.

FIG. 2 is an enlarged plan view illustrating a structure of a pixel disposed in a light emitting display device according to a first embodiment of the present disclosure.

FIG. 3 is an enlarged cross-sectional view, cutting along line I-I’ in FIG. 2, for illustrating a structure of a light emitting display device according to the first embodiment of the present disclosure.

FIG. 4 is an enlarged plan view illustrating a structure of a pixel disposed in a light emitting display device according to a second embodiment of the present disclosure.

FIG. 5 is an enlarged cross-sectional view, cutting along line II-II’ in FIG. 4, for illustrating a structure of a light emitting display device according to the second embodiment of the present disclosure.

FIG. 6 is an enlarged plan view illustrating a structure of three pixels serially disposed in a light emitting display device according to a third embodiment of the present disclosure.

FIG. 7 is an enlarged cross-sectional view, cutting along line III-III’ in FIG. 6, for illustrating a structure of a light emitting display device according to the third embodiment of the present disclosure.

FIG. 8 is an enlarged plan view illustrating a structure of three pixels serially disposed in a light emitting display device according to a fourth embodiment of the present disclosure.

FIG. 9 is an enlarged cross-sectional view, cutting along line IV-IV’ in FIG. 8, for illustrating a structure of a light emitting display device according to the fourth embodiment of the present disclosure.

### DETAILED DESCRIPTION OF THE DISCLOSURE

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example embodiments of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function or configuration may be omitted.

Reference will now be made in detail to the exemplary embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked”, “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and/or the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, an example of a display device according to the present disclosure will be described in detail with reference to the attached drawings. Wherever possible, the same reference numbers will be used throughout the drawings to refer to the same or like parts.

Hereinafter, referring to the attached figures, the present disclosure will be explained. Since a scale of each of elements shown in the accompanying drawings may be different from an actual scale for convenience of description, the present disclosure is not limited to the scale shown in the drawings.

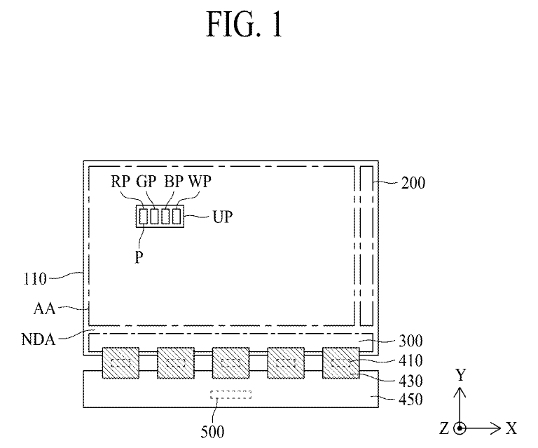

FIG. 1 is a plan view illustrating a schematic structure of a light emitting display device according to an embodiment of the present disclosure. In FIG. 1, X-axis refers to the direction parallel to the scan line, Y-axis refers to the direction parallel to the data line, and Z-axis refers to the thickness (or height) direction of the display device.

Referring to FIG. 1, the light emitting display device, for example, an electroluminescence display comprises a substrate 110, a gate (or scan) driver 200, a pad portion 300, a source driving IC (Integrated Circuit) 410, a flexible circuit film 430, a circuit board 450, and a timing controller 500. A plurality of pixels P may be arrayed on the substrate 110. For example, a red pixel RP, a green pixel GP, a blue pixel BP and a white pixel WP may be sequentially arrayed in a horizontal (X-axis) direction. One group of a red pixel RP, a green pixel GP, a blue pixel BP and a white pixel WP may configure a unit pixel UP.

The substrate 110 may include an electrical insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. In the display area AA, a plurality of pixels P are arrayed in a matrix manner. Further, a plurality of scan lines (or gate lines), a plurality of data lines may be disposed as crossing each other. Each of pixels P may be disposed at the crossing area of the scan line running to X-axis and the data line running to Y-axis.

Here, a pixel P may represent any one of color among red, green, blue or white. A red pixel RP, a green pixel GP, a blue pixel BP and a white pixel WP may be gathered to form one unit pixel UP. For example, each of the pixels representing each color may be called a ‘pixel P’, and four of ‘pixels P’are gathered to form one ‘unit pixel UP’.

The non-display area NDA, which is an area not representing the video images, may be defined at the circumference areas of the substrate 110 surrounding all or some of the display area AA. In the non-display area NDA, the gate driver 200 and the pad portion 300 may be formed or disposed.

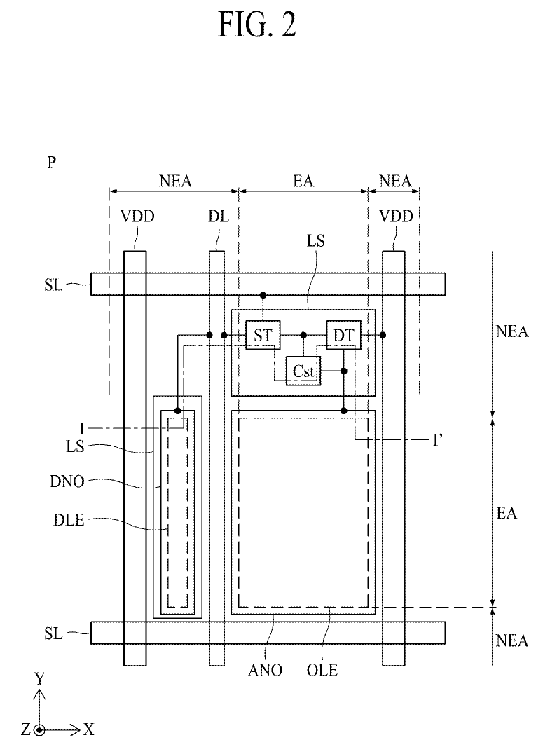

The gate driver 200 may supply the scan (or gate) signals to the scan lines SL (see FIG. 2) according to the gate control signal received from the timing controller 500 through the pad portion 300. The gate driver 200 may be formed at the non-display area NDA at any one outside of the display area DA on the substrate 110, as a GIP (Gate driver In Panel) type. GIP type means that the gate driver 200 is directly formed on the substrate 110. For example, the gate driver 200 may be configured with shift registers. In the GIP type, the transistors for shift registers of the gate driver 200 are directly formed on the upper surface of the substrate 110.

The pad portion 300 may be disposed in the non-display area NDA at one side edge of the display area AA of the substrate 110. The pad portion 300 may include data pads connected to each of the data lines DL, driving current pads connected to the driving current lines, a high-potential pad receiving a high potential voltage, and a low-potential pad receiving a low potential voltage.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (Chip On Film) or COP (Chip On Plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430.

The circuit board 450 may be attached to the flexible circuit film 430. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be integrated with the source driving IC 410 into one driving chip and may be mounted on the substrate 110 to be connected to the pad portion 300.

### First Embodiment

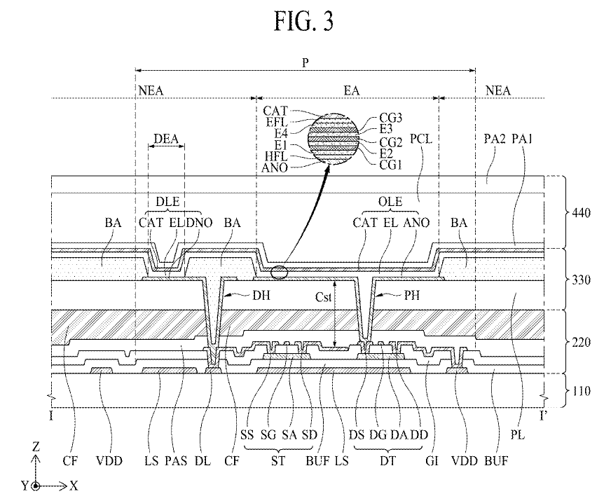

Hereinafter, referring to FIGS. 2 and 3, a detailed structure of a light emitting display device according to a first embodiment of the present disclosure will be explained. FIG. 2 is an enlarged plan view illustrating a structure of a pixel disposed in a light emitting display device according to a first embodiment of the present disclosure. FIG. 3 is an enlarged cross-sectional view, cutting along line I-I’ in FIG. 2, for illustrating a structure of a light emitting display device according to the first embodiment of the present disclosure.

Referring to FIG. 2, one pixel P of the light emitting display device according to the first embodiment of the present disclosure may include an emission area EA and a non-emission area NEA. The emission area EA may be the area that provides light and displays image information. The non-emission area NEA may be an area surrounding the emission area EA, and may not display image information.

The scan line SL may run along the first direction (X axis), and may be arranged at regular intervals along the second direction (Y axis) intersecting the first direction (X axis). The display area AA of the substrate 110 may include a plurality of scan lines SL that are spaced apart from each other along the second direction (Y axis) and parallel to the first direction (X axis). Here, the first direction (X axis) may be defined as a horizontal (or lateral) direction on a surface of the substrate 110, and the second direction (Y axis) may be defined as a vertical direction on the surface of the substrate 110. However, it is not limited thereto, and may be defined as opposite manner.

The data line DL may extend along the second direction (Y axis) and be arranged at regular intervals along the first direction (X axis). The display area AA of the substrate 110 may include a plurality of data lines DL spaced apart from each other along the first direction (X axis) and be parallel to the second direction (Y axis).

The driving current line VDD may be arranged on the substrate 110 as being parallel to the data line DL. However, it is not limited thereto. In some cases, the driving current line VDD may be arranged as being parallel to scan line SL. The driving current line VDD may be supplied with a high-level voltage for driving the light emitting diode OLE.

A pixel P may include a driving element electrically connected to the scan line SL, the data line DL and the driving current line VDD, and a light emitting element electrically connected to the driving element. In detail, the pixel P may be surrounded by the scan line SL, the data line DL and the driving current line VDD. Each pixel P of the light emitting display device according to the present disclosure may be defined by a scan line SL, a data line DL and a driving current line VDD. Each pixel P of the light emitting display may include a switching thin film transistor ST, a driving thin film transistor DT, a light emitting diode OLE, a storage capacitance (or capacitor) Cst and a compensation light emitting diode DLE. The driving current line VDD may be supplied with a high-level voltage for driving the light emitting diode OLE.

The switching thin film transistor ST may be disposed between the data line DL and the scan line SL. The switching thin film transistor ST may transmit an electric signal of the data line DL to the gate electrode DG of the driving thin film transistor DT when a gate voltage is applied to the scan line SL. That is, a switching thin film transistor ST may be a device that selects and drives a driving thin film transistor DT.

The driving thin film transistor DT may be disposed between the driving current line VDD and the light emitting diode OLE. The driving thin film transistor DT may control the amount of current flowing from the driving current line VDD to the light emitting diode OLE according to the voltage difference between the gate electrode DG and the source electrode DS. The light emitting diode OLE may display an image by emitting light according to the current controlled by a driving then film transistor DT.

The light emitting diode OLE may be connected to the driving thin film transistor DT. The light emitting diode OLE may be disposed as corresponding to the emission area EA. Referring to FIG. 3, the light emitting diode OLE may have a structure in which a pixel electrode ANO, an emission layer EL and a common electrode CAT may be sequentially stacked. When holes are supplied from the pixel electrode ANO and electrons are supplied from the common electrode CAT, the electrons and holes may combine at the emission layer EL to generate excitons. As the excitons change from the excited state to the ground state, the fluorescent molecules in the emission layer EL may emit lights, thereby representing colors.

The dummy light emitting diode DLE may be connected to the source electrode SS of the switching thin film transistor ST and a data line DL. The dummy light emitting diode DLE may be disposed within the non-emission area NEA. The driving element and the dummy light emitting diode DLE may be disposed within the non-emission area NEA. Here, the driving element may include a scan line SL, a data line DL, a driving current line VDD, a switching thin film transistor ST, a capacitor Cst and a driving thin film transistor DT. The dummy light emitting diode DLE may have a structure in which the dummy pixel electrode DNO, an emission layer EL and a common electrode CAT are sequentially stacked. Therefore, the dummy light emitting diode DLE may generate the light at the emission layer EL as the light emitting diode OLE.

The light shielding layer LS may be disposed under the switching thin film transistor ST, the capacitor Cst and the driving thin film transistor DT among the driving elements to block the light intrusion from outside. The light shielding layer LS may be disposed between the substrate 110 and a driving element layer 220. In addition, the light shielding layer LS may be disposed under the dummy light emitting diode DLE in the non-emission area NEA, so that the lights generated from the dummy light emitting diode DLE may be blocked not to be provided to outside of the substrate 110.

Hereinafter, referring to FIG. 3, a cross-sectional structure of the light emitting display device according to the first embodiment will be explained. Referring to FIG. 3, a cross-sectional shape of the light emitting display device according to the first embodiment may have a structure in which a substrate 110, a driving element layer 220, a light emitting element layer 330 and an encapsulation layer 440 are sequentially stacked.

On the substrate 110, a light shielding layer LS, a data line DL and a driving current line VDD may be formed. The light shielding layer LS, the data line DL and the driving current line VDD may be formed of a metal material having excellent conductivity and opaque property. For example, the light shielding layer LS, the data line DL and the driving current line VDD may be made of any one of molybdenum (Mo), nickel (Ni), titanium (Ti), copper (Cu), aluminum (Al), tantalum (Ta) and alloy thereof. The driving element layer 220 on the substrate 110 may include the data line DL, the driving current line VDD and the scan line SL in each pixel, the switching thin film transistor ST between the data line DL and the scan line SL and the driving thin film transistor DT between the switching thin film transistor ST and the driving current line VDD.

On the light shielding layer LS, the data line DL and the driving current line VDD, a buffer layer BUF may be deposited as covering entire surface of the substrate 110. The buffer layer BUF may be made of an inorganic material such as silicon oxide SiOx or silicon nitride SiNx.

The switching thin film transistor ST, the driving thin film transistor DT and the capacitor Cst may be formed on the buffer layer BUF. The switching thin film transistor ST may include a gate electrode SG, a semiconductor layer SA, a source electrode SS and a drain electrode SD. The driving thin film transistor DT may include a gate electrode DG, a semiconductor layer DA, a source electrode DS and a drain electrode DD.

In detail, the semiconductor layer SA of the switching thin film transistor ST and the semiconductor layer DA of the driving thin film transistor DT may be formed on the buffer layer BUF. It is preferable that the semiconductor layers SA and DA are disposed as being overlapped with the light shielding layer LS. The light shielding layer LS may be an element for preventing lights from entering from outside the substrate 110 and affecting the semiconductor layers SA and DA. The semiconductor layers SA and DA may be made of any one of low temperature poly-silicon (LTPS) material, oxide semiconductor material and amorphous silicon (a-Si) material. For example, the oxide semiconductor material may include indium-gallium zinc oxide (IGZO).

A gate insulating layer GI may be deposited on the semiconductor layer SA and DA as covering entire surface of the substrate 110. The gate electrode SG of the switching thin film transistor ST and the gate electrode DG of the driving thin film transistor DT may be formed on the gate insulating layer GI. Each of the gate electrodes SG and DG may be disposed as being overlapped with a corresponding one of the semiconductor layer SA and DA, respectively. The overlapped portions of the semiconductor layers SA and DA with the gate electrodes SG and DG may be defined as the channel areas.

The source electrode SS and the drain electrode SD of the switching thin film transistor ST and the source electrode DS and the drain electrode DD of the driving thin film transistor DT may be formed on the gate insulating layer GI. The source electrode SS of the switching thin film transistor ST may be connected to one side of the semiconductor layer SA of the switching thin film transistor ST. The drain electrode SD of the switching thin film transistor ST may be connected to another side of the semiconductor layer SA of the switching thin film transistor ST. Similarly, the source electrode DS of the driving thin film transistor DT may be connected to one side of the semiconductor layer DA of the driving thin film transistor DT. The drain electrode DD of the driving thin film transistor DT may be connected to another side of the semiconductor layer DA of the driving thin film transistor DT.

The gate electrodes SG and DG, the source electrodes SS and DS and the drain electrodes DS and DD are formed on the gate insulating layer GI, but they are spaced apart from each other. Even though it is not shown in figures, a scan line SL for connecting the gate electrodes SG of the switching thin film transistors ST may be disposed on the gate insulating layer GI. It is not limited thereto, an insulating layer may be further deposited on the gate electrode, and the source electrode and the drain electrode may be formed on the insulating layer. For another example, the gate electrode may be disposed under the semiconductor layer in the bottom gate structure. For still another example, the source electrode and the drain electrode may be formed at first, a semiconductor layer may be formed thereon, a gate insulating layer may be deposited on the semiconductor layer, and a gate electrode may be formed on the gate insulating layer.

The source electrode SS of the switching thin film transistor ST may be connected to the data line DL via a contact hole penetrating the gate insulating layer GI and the buffer layer BUF. In addition, the drain electrode DD of the driving thin film transistor DT may be connected to the driving current line VDD via a contact hole penetrating the gate insulating layer GI and the buffer layer BUF.

A passivation layer PAS may be deposited on the driving element including the scan line SL, the data line DL, the driving current line VDD, the switching thin film transistor ST and the driving thin film transistor DT as covering entire surface of the substrate 110. A color filter CF may be deposited on the passivation layer PAS. The color filter CF may be disposed between the driving element layer 220 and the pixel electrode ANO. The color filter CF may include a red color filter, a green color filter, a blue color filter and a white color filter. The red color filter may be corresponding to the red pixel RP, the green color filter may be corresponding to the green pixel GP, the blue color filter may be corresponding to the blue pixel BP and the white color filter may be corresponding to the white pixel WP.

The light emitting element layer 330 may be formed on the color filter CF. The light emitting element layer 330 may include the planarization layer PL, the light emitting diode OLE and the dummy light emitting diode DLE. The light emitting diode OLE may include a pixel electrode ANO, an emission layer EL and a common electrode CAT. The dummy light emitting diode DLE may include a dummy pixel electrode DNO, the emission layer EL and the common electrode CAT. The dummy pixel electrode DNO may be disposed at least one side of the pixel electrode ANO in each pixel. The dummy pixel electrode DNO may be connected to any one of the data line DL, the switching thin film transistor ST and the driving thin film transistor DT.

In detail, the planarization layer PL may be deposited on the color filter CF as covering entire surface of the substrate 110. The planarization layer PL may be made of one layer, or multiple layers. The planarization layer PL may be a layer used to flatten the uneven surface of the substrate 110 on which the driving elements are formed. In order to equalize or compensate the height difference due to the uneven surface condition, the planarization layer PL may be formed of an organic material. The passivation layer PAS, the color filter CF and the planarization layer PL may have a pixel contact hole PH exposing some of the source electrode DS of the driving thin film transistor DT.

The pixel electrode ANO may be formed on the planarization layer PL as having a size corresponding to the emission area EA. The pixel electrode ANO may have a little bigger size than the emission area EA. The pixel electrode ANO may be connected to the source electrode DS of the driving thin film transistor DT via the pixel contact hole PH.

The dummy pixel electrode DNO may be disposed within the non-emission area NEA on the planarization layer PL. In particular, the dummy pixel electrode DNO may be disposed as being fully overlapped with the light shielding layer LS. The light shielding layer LS may overlap the dummy pixel electrode DNO without overlapping the pixel electrode ANO. The pixel electrode ANO and the dummy pixel electrode DNO may be connected to a driving element disposed in the driving element layer 220. For example, the dummy pixel electrode DNO may be disposed at a side (e.g., left side) of the pixel electrode ANO. The data line DL may be disposed at left side of the pixel electrode ANO. The dummy pixel electrode DNO may be disposed at left side of the data line DL. In particular, the dummy pixel electrode DNO may be disposed as being overlapped with the light shielding layer LS located at the left side of the data line DL. The dummy pixel electrode DNO may be connected to the source electrode SS of the switching thin film transistor ST via a dummy contact hole DH penetrating the planarization layer PL, the color filter CF and the passivation layer PAS. Further, the source electrode SS may be connected to the data line DL, so the dummy pixel electrode DNO may also be connected to the data line DL.

The pixel electrode ANO and the dummy pixel electrode DNO may have various structure in accordance with the emission structure of the light emitting diode OLE. For the bottom emission type in which lights are provided to the substrate 110, the pixel electrode ANO and the dummy pixel electrode DNO may include a transparent conductive material. For example, the pixel electrode ANO and the dummy pixel electrode DNO may be made of at least any one of indium-tin oxide (ITO), indium-zinc oxide (IZO) and indium-gallium-zinc oxide (IGZO).

A bank BA may be deposited at the circumferences of the pixel electrode ANO to define the emission area EA. Further, the bank BA may be deposited at the circumferences of the dummy pixel electrode DNO to define the dummy emission area DEA.

An emission layer EL may be deposited on the surfaces of the pixel electrode ANO, the dummy pixel electrode DNO and the bank BA. The emission layer EL may be deposited as covering all pixels P arrayed on the substrate 110, and may have one sheet shape continuously deposited on entire surface of the substrate 110.

The emission layer EL may have a structure in which a hole functional layer HFL, an organic light emitting layer and an electron functional layer EFL are sequentially stacked. The hole functional layer HFL may be in surface contact with the pixel electrode ANO and the dummy pixel electrode DNO. The electron functional layer EFL may be deposited on the organic light emitting layer. The organic light emitting layer may have a structure in which a first emission layer E1, a first charge generation layer CG1, a second emission layer E2, a second charge generation layer CG2, a third emission layer E3, a third charge generation layer CG3 and a fourth emission layer E4 are sequentially stacked. However, it is not limited thereto, the organic light emitting layer may have a structure in which a first emission layer, a charge generation layer and a second emission layer are sequentially stacked. For another example, the organic light emitting layer may have a structure in which a first emission layer, a first charge generation layer, a second emission layer, a second charge generation layer and a third emission layer are sequentially stacked.

The first emission layer E1 may include an organic light emitting material configured to provide red lights. The second emission layer E2 may include an organic light emitting material configured to provide blue lights. The third emission layer E3 may include an organic light emitting material configured to provide green lights. The fourth emission layer E4 may include an organic light emitting material configured to provide blue lights. The second emission layer E2 and the fourth emission layer E4 may include same organic light emitting material configured to provide blue lights. Otherwise, the second emission layer E2 and the fourth emission layer E4 may be made of different organic light emitting materials to provide different blue lights (e.g., blue lights with different brightness or saturation). For example, the second emission layer E2 may include an organic light emitting material providing first blue lights. The fourth emission layer E4 may include an organic light emitting material providing second blue lights.

The first emission layer E1, the second emission layer E2, the third emission layer E3 and the fourth emission layer E4 may be stacked so that their colors are mixed. Ultimately, the emission layer EL may provide white lights. However, it is not limited thereto, depending on the amount of combination of the first emission layer E1, the second emission layer E2, the third emission layer E3 and the fourth emission layer E4, the emission layer EL may provide blue lights or green lights. Hereinafter, for convenience, it is explained as providing white lights. For bottom emission type, as white colors of light are passing through the color filter CF, color lights assigned to each pixel P may be emitted out. Even though it is not shown in figures, for the case of the top emission type, as white colors of light pass through the color filter CF disposed at upper position of the light emitting diode OLE, color lights assigned to each pixel P may be emitted out. In addition, a color conversion layer may be disposed between the light emitting diode OLE and the color filter CF.

A common electrode CAT may be deposited on the emission layer EL. The common electrode CAT may be deposited as covering all pixels P disposed on the substrate 110, and may have one sheet shape continuously deposited as covering entire surface of the substrate 110. For the bottom emission type, the common electrode CAT may include a metal material having excellent light reflectance. For example, the common electrode CAT may be made of any one of silver (Ag), molybdenum (Mo), titanium (Ti), tantalum (Ta), aluminum (Al) and copper (Cu), or any alloy thereof.

An encapsulation layer 440 may be deposited on the light emitting element layer 330. The encapsulation layer 440 may have a structure in which a first inorganic layer PA1, an organic layer PCL and a second inorganic layer PA2 may be sequentially stacked. The first inorganic layer PA1 may be deposited on the common electrode CAT. The organic layer PCL may be deposited on the first inorganic layer PA1. The second inorganic layer PA2 may be deposited on the organic layer PCL.

Even though it is not shown in figures, the encapsulation layer 440 may include an adhesive material having a moisture absorbent. In addition, the adhesive material may be disposed at the outermost circumference of the substrate 110 as a dam structure. Further, an encapsulation substrate made of a metal plate or a glass plate may be attached on the substrate 110 using the adhesive material.

A light emitting diode OLE may be formed in the emission area EA of the pixel P. Further, the dummy light emitting diode DLE may be formed at the dummy emission area DEA in the non-emission area NEA. In the emission area EA as a first region, lights generated from the light emitting diode OLE may be emitted to the outside through the substrate 110. However, in the dummy emission area DEA as a second region, lights generated from the dummy light emitting diode DLE which is disposed corresponding to the light shielding layer LS may be blocked by the light shielding layer LS so that it is not emitted to the outside.

The dummy light emitting diode DLE may be disposed between a first light emitting diode and a second light emitting diode located at a left side of the first light emitting diode. When the second light emitting diode is operated, the lateral leakage currents may be flown to the dummy light emitting diode DLE through the first charge generation layer CG1, the second charge generation layer CG2 and the third charge generation layer CG3. When the dummy light emitting diode DLE is operated, the leakage current may cause the dummy light emitting diode DLE to emit lights brighter than its original brightness. Even though lights are emitted from the dummy light emitting diode DLE, these lights may not be emitted to the outside by the light shielding layer LS, so the lights from the dummy light emitting diode DLE that may emit lights with high brightness may not be perceived by the user.

In the light emitting display device according to the present disclosure, when the dummy light emitting diode DLE or the dummy pixel electrode DNO is not included, due to the lateral leakage current of the second light emitting diode located at the left side of the first light emitting diode, the first light emitting diode OLE may emit light that is brighter than its original brightness. Accordingly, the first light emitting diode OLE may not provide normal brightness, so the image information may be distorted. However, the light emitting display device according to the present disclosure includes a dummy light emitting diode DLE between two neighboring pixels P or includes a dummy pixel electrode DNO disposed at least one side of the pixel electrode ANO. The dummy light emitting diode DLE may absorb the lateral leakage current generated at the neighboring pixel P, and emit lights by consuming the leakage current, so the lateral leakage current may not affect the light emitting diode OLE. Accordingly, it may prevent the problem of pixels P brightness becoming abnormally high due to leakage current.

### Second Embodiment

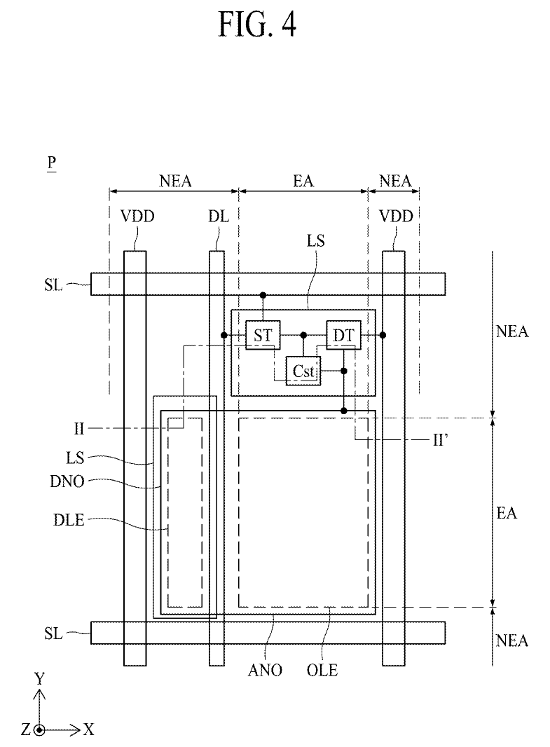

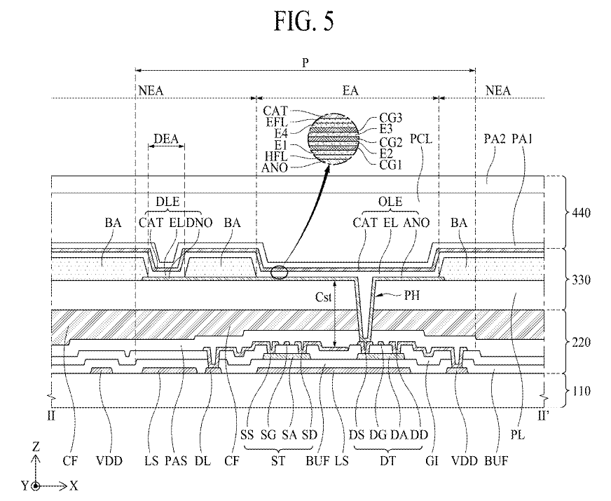

Hereinafter, referring to FIGS. 4 and 5, a detailed structure of a light emitting display device according to a second embodiment will be explained. FIG. 4 is an enlarged plan view illustrating a structure of a pixel disposed in a light emitting display device according to a second embodiment of the present disclosure. FIG. 5 is an enlarged cross-sectional view, cutting along line II-II’ in FIG. 4, for illustrating a structure of a light emitting display device according to the second embodiment of the present disclosure.

The light emitting display device according to the second embodiment may have a structure very similar to that of the first embodiment. The difference may be in the structure in which the dummy pixel electrode DNO is connected to the driving element. In following explanation, detailed description of the same elements as in the first embodiment may not be duplicated or briefly described. For elements shown in FIGS. 4 and 5 but not described, refer to the description of the first embodiment. Additionally, variously changed structures may be applied in the same or similar manner as described in the first embodiment.

Referring to FIG. 4, the light emitting display device according to the second embodiment of the present disclosure may include a plurality of pixels P. One pixel P may include an emission area EA and a non-emission area NEA. The emission area EA may be the region for providing lights and displaying image information. The non-emission area NEA may be the region surrounding the emission area EA, where no image information is displayed.

The scan lines SL may be extended along the first direction (X axis) and be arranged at regular intervals along the second direction (Y axis) intersecting the first direction (X axis). The data lines DL may be extended along the second direction (Y axis) and be arranged at regular intervals along the first direction (X axis). The driving current line VDD may be disposed on the substrate 110 as being parallel to the data lines DL.

The pixel P may include a driving element which is connected to a scan line SL, a data line DL and a driving current line VDD, and a light emitting element which is connected to the driving element. In detail, the pixel P may be defined by a scan line SL, a data line DL and a driving current line VDD surrounding the pixel P. One pixel P of the light emitting display device may include a switching thin film transistor ST, a driving thin film transistor DT, a light emitting diode OLE, a capacitor Cst and a dummy light emitting diode DLE.

The switching thin film transistor ST may be disposed between a data line DL and a scan line SL. The driving thin film transistor DT may be disposed between a driving current line VDD and a light emitting diode OLE. The light emitting diode OLE may be connected to the driving thin film transistor DT. The light emitting diode OLE may be disposed as corresponding to the emission area EA.

The dummy light emitting diode DLE may be connected to the light emitting diode OLE. For example, the dummy pixel electrode DNO of the dummy light emitting diode DLE may be formed by extending the pixel electrode ANO of the light emitting diode OLE into the non-emission area NEA. In another words, the pixel electrode ANO may be extended to the non-emission area NEA, so the extended portion of the pixel electrode ANO may be the dummy pixel electrode DNO.

Referring to FIG. 5, a cross-sectional structure of the light emitting display device according to the second embodiment will be explained. Referring to FIG. 5, in the cross-sectional structure of the light emitting display device according to the second embodiment, a substrate 110, a driving element layer 220, a light emitting element layer 330 and an encapsulation layer 440 are sequentially stacked.

A light shielding layer LS, a data line DL and a driving current line VDD may be formed on the substrate 110. A buffer layer BUF may be deposited on the light shielding layer LS, the data line DL and the driving current line VDD as covering entire surface of the substrate 110. A switching thin film transistor ST, a driving thin film transistor DT and a capacitor Cst may be formed on the buffer layer BUF.

A passivation layer PAS may be deposited on the driving elements including the scan line SL, the data line DL, the driving current line VDD, the switching thin film transistor ST and the driving thin film transistor DT, as covering entire surface of the substrate 110. A color filter CF may be deposited on the passivation layer PAS.

A light emitting element layer 330 may be deposited on the color filter CF. The light emitting element layer 330 may include a planarization layer PL, a light emitting diode OLE and a dummy light emitting diode DLE. The planarization layer PL on the color filter CF may be deposited as covering entire surface of the substrate 110.

The light emitting diode OLE may include a pixel electrode ANO, an emission layer EL and a common electrode CAT. The dummy light emitting diode DLE may include a dummy pixel electrode DNO, the emission layer EL and the common electrode CAT. A pixel contact hole PH may be formed at the passivation layer PAS, the color filter CF and the planarization layer PL for exposing some of the source electrode DS of the driving thin film transistor DT.

The pixel electrode ANO and the dummy pixel electrode DNO may be formed on the planarization layer PL. The pixel electrode ANO may be connected to the source electrode DS of the driving thin film transistor DT via the pixel contact hole PH. The dummy pixel electrode DNO may be connected to the source electrode DS of the driving thin film transistor DT via the pixel contact hole PH. The pixel electrode ANO may be disposed as being corresponding to the emission area EA. The dummy pixel electrode DNO may be arranged such that the pixel electrode ANO extends to the dummy emission area DEA. That is, the pixel electrode ANO and the dummy pixel electrode DNO may be formed as one thin layer. For the case of the bottom emission type, the pixel electrode ANO and the dummy pixel electrode DNO may be made of a transparent conductive material. Here, the dummy pixel electrode DNO may be overlapped with the light shielding layer LS.

A bank BA may be formed on the pixel electrode ANO and the dummy pixel electrode DNO having one thin layer shape, so the bank BA may define the emission area EA and the dummy emission area DEA. The emission area EA may be corresponding to middle portions of the pixel electrode ANO, and the non-emission area NEA may be corresponding to middle portions of the dummy pixel electrode DNO. That is, the connected portion between the pixel electrode ANO and the dummy pixel electrode DNO may be covered by the bank BA, so that the bank BA may distinguish or separate the emission area EA from the dummy emission area DEA.

An emission layer EL may be deposited on the surfaces of the pixel electrode ANO, the dummy pixel electrode DNO and the bank BA. The emission layer EL may be deposited on the substrate 110 as covering all pixels P, and have one-sheet shape continuous over entire surface of the substrate 110.

The emission layer EL may have a structure in which a hole functional layer HFL, an organic light emitting layer and an electron functional layer EFL are sequentially stacked. The organic light emitting layer may have a structure in which a first emission layer E1, a first charge generation layer CG1, a second emission layer E2, a second charge generation layer CG2, a third emission layer E3, a third charge generation layer CG3 and a fourth emission layer E4 are sequentially stacked.

A common electrode CAT may be deposited on the emission layer EL. The common electrode CAT may be deposited as covering all pixels P disposed on the substrate 110, and may have one-sheet shape continuously deposited as covering entire surface of the substrate 110. For the bottom emission type, the common electrode CAT may include a metal material having excellent light reflectance.

An encapsulation layer 440 may be deposited on the light emitting element layer 330. The encapsulation layer 440 may have a structure in which a first inorganic layer PA1, an organic layer PCL and a second inorganic layer PA2 may be sequentially stacked.

A light emitting diode OLE may be formed in the emission area EA of the pixel P. Further, the dummy light emitting diode DLE may be formed at the dummy emission area DEA in the non-emission area NEA. Lights generated from the light emitting diode OLE may be emitted to the outside through the substrate 110. However, lights generated from the dummy light emitting diode DLE may be blocked by the light shielding layer LS so that the lights are not emitted to the outside.

The dummy light emitting diode DLE may be disposed between a first light emitting diode and a second light emitting diode located at left side of the first light emitting diode. When the second light emitting diode is operated, the lateral leakage currents may be flown to the dummy light emitting diode DLE through the first charge generation layer CG1, the second charge generation layer CG2 and the third charge generation layer CG3. When the dummy light emitting diode DLE is operated, the leakage current may cause the dummy light emitting diode DLE to emit lights brighter than its original brightness. Even though lights are emitted from the dummy light emitting diode DLE, these lights may not be emitted to the outside because of the light shielding layer LS, so the lights from the dummy light emitting diode DLE, which may emit lights with high brightness, may not be perceived by the user.

The dummy light emitting diode DLE may absorb the lateral leakage current generated at the neighboring pixel P, and emit lights by consuming the leakage current, so the lateral leakage current may not affect the light emitting diode OLE. Accordingly, it may prevent the problem of pixels P brightness becoming abnormally distorted due to leakage current.

### Third Embodiment

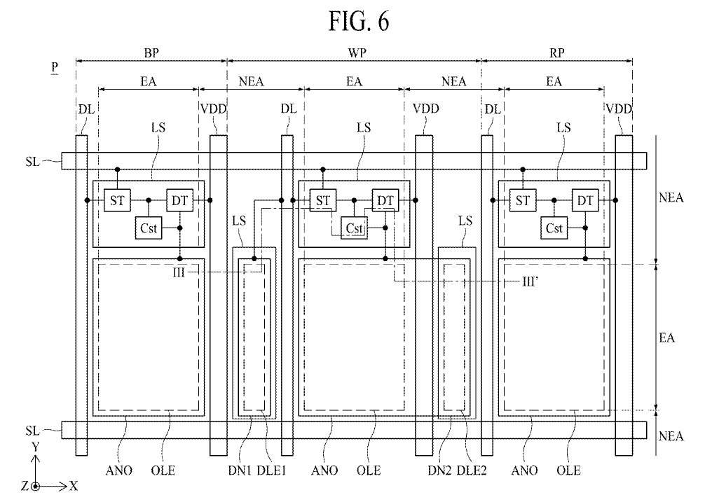

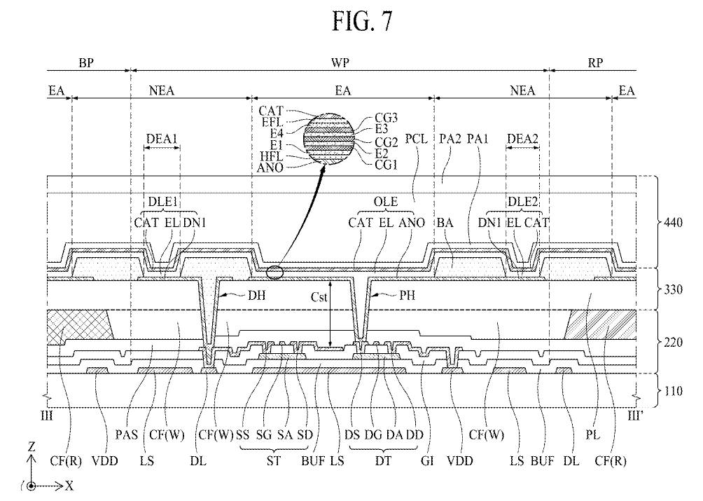

Hereinafter, referring to FIGS. 6 and 7, a detailed structure of a light emitting display device according to a third embodiment will be explained. FIG. 6 is an enlarged plan view illustrating a structure of three pixels serially disposed in a light emitting display device according to a third embodiment of the present disclosure FIG. 7 is an enlarged cross-sectional view, cutting along line III-III’ in FIG. 6, for illustrating a structure of a light emitting display device according to the third embodiment of the present disclosure.

In the first embodiment and the second embodiment, the structure of one pixel P among the plurality of pixels P arrayed on the substrate 110 is explained. Therefore, all pixels P arrayed on the substrate 110 may have the same structure.

For the case that one unit pixel UP include white pixel WP, the white pixel WP may be most affected by the lateral leakage current, which may cause distortion in luminance representation. In the third embodiment and the fourth embodiment, by disposing the dummy light emitting diode DLE at both sides of the white pixel WP, the structures may be proposed to prevent the light emitting diode of the white pixel WP from being affected by the lateral leakage current.

The light emitting display device according to the third embodiment may have a structure very similar to that of the first embodiment. In following explanation, detailed description of the same elements as in the first embodiment may not be duplicated or briefly described. For elements shown in FIGS. 6 and 7 but not described, refer to the description of the first embodiment.

As shown in FIG. 1, by arranging a red pixel RP, a green pixel GP, a blue pixel BP and a white pixel WP on the substrate 110, one unit pixel UP may be formed. In the third embodiment, the explanation will be described as focusing on the white pixel WP. As shown in FIG. 6, a blue pixel BP, a white pixel WP and a red pixel RP may be arranged continuously on the surface of the substrate 110. A green pixel GP may be disposed next to the red pixel RP, but it is not mentioned in the drawing. However, it is not limited thereto, a red pixel RP, a white pixel WP and a green pixel GP may be arranged continuously on the surface of the substrate 110.

The white pixel WP may include an emission area EA and a non-emission area NEA. Each of the blue pixel BP and the red pixel RP may include the emission area EA and the non-emission area NEA. The emission area EA may be the region for providing lights and displaying image information. The non-emission area NEA may be the region surrounding the emission area EA, where no image information is displayed.

The scan lines SL may be extended along the first direction (X axis) and be arranged at regular intervals along the second direction (Y axis) intersecting the first direction (X axis). The data lines DL may be extended along the second direction (Y axis) and be arranged at regular intervals along the first direction (X axis). The driving current line VDD may be disposed on the substrate 110 as being parallel to the data lines DL.

Each of the blue pixel BP, the white pixel WP and the red pixel RP may include a driving element which is connected to a scan line SL, a data line DL and a driving current line VDD, and a light emitting element which is connected to the driving element. Each of the blue pixel BP, the white pixel WP and the red pixel RP may be defined as being surrounded by a scan line SL, a data line DL and a driving current line VDD. Each of the blue pixel BP and the red pixel RP may include a switching thin film transistor ST, a driving thin film transistor DT, a light emitting diode OLE and a capacitor Cst.

The white pixel WP may include a switching thin film transistor ST, a driving thin film transistor DT, a light emitting diode OLE, a capacitor Cst, a first dummy light emitting diode DLE1 and a second dummy light emitting diode DLE2. The first dummy light emitting diode DLE1 may be disposed between the white pixel WP and the blue pixel BP. The second dummy light emitting diode DLE2 may be disposed between the white pixel WP and the red pixel RP.

The following description may focus on the white pixel WP. The switching thin film transistor ST of the white pixel WP may be disposed between a data line DL and a scan line SL. The driving thin film transistor DT of the white pixel WP may be disposed between a driving current line VDD and a light emitting diode OLE. The light emitting diode OLE of the white pixel WP may be connected to the driving thin film transistor DT. The light emitting diode OLE may be disposed as corresponding to the emission area EA.

The first dummy light emitting diode DLE1 may be connected to the source electrode SS of the switching thin film transistor ST in the white pixel WP or to the data line DL. For example, a first dummy pixel electrode DN1 of the first dummy light emitting diode DLE1 may be separated from the pixel electrode ANO of the light emitting diode OLE in the white pixel WP. The second dummy light emitting diode DLE2 may be connected to the light emitting diode OLE of the white pixel WP. For example, a second dummy pixel electrode DN2 of the second dummy light emitting diode DLE2 may be formed by extending the pixel electrode ANO to the non-emission area NEA positioned on its right side.

Further, referring to FIG. 7, a cross-sectional structure of the light emitting display device according to the third embodiment will be explained. Referring to FIG. 7, in the cross-sectional structure of the light emitting display device according to the third embodiment, a substrate 110, a driving element layer 220, a light emitting element layer 330 and an encapsulation layer 440 are sequentially stacked.

A light shielding layer LS, a data line DL and a driving current line VDD may be formed on the substrate 110. A buffer layer BUF may be deposited on the light shielding layer LS, the data line DL and the driving current line VDD as covering entire surface of the substrate 110. A switching thin film transistor ST, a driving thin film transistor DT and a capacitor Cst may be formed on the buffer layer BUF.

A passivation layer PAS may be deposited on the driving elements including the scan line SL, the data line DL, the driving current line VDD, the switching thin film transistor ST and the driving thin film transistor DT, as covering entire surface of the substrate 110. A color filter CF may be deposited on the passivation layer PAS. The blue pixel BP may include a blue color filter CF(B), and the red pixel RP may include a red color filter CF®. The white pixel WP may include a transparent color filter CF(W). In some cases, the white pixel WP may have no color filter.

A light emitting element layer 330 may be deposited on the color filter CF. The light emitting element layer 330 may include a planarization layer PL, a light emitting diode OLE, a first dummy light emitting diode DLE1 and a second dummy light emitting diode DLE2. The planarization layer PL on the color filter CF may be deposited as covering entire surface of the substrate 110.

The light emitting diode OLE may include a pixel electrode ANO, an emission layer EL and a common electrode CAT. The first dummy light emitting diode DLE1 may include a first dummy pixel electrode DN1, the emission layer EL and the common electrode CAT. The second dummy light emitting diode DLE2 may include a second dummy pixel electrode DN2, the emission layer EL and the common electrode CAT. A pixel contact hole PH may be formed at the passivation layer PAS, the white color filter CF(W) and the planarization layer PL for exposing some of the source electrode DS of the driving thin film transistor DT. Further, a dummy contact hole DH may be formed at the passivation layer PAS, the white color filter CF(W) and the planarization layer PL for exposing some of the source electrode SS of the switching thin film transistor ST.

The pixel electrode ANO, the first dummy pixel electrode DN1 and the second dummy pixel electrode DN2 may be formed on the planarization layer PL. The first dummy pixel electrode DN1 and the second dummy pixel electrode DN2 may be fully overlapped with the light shielding layer LS. The pixel electrode ANO may be connected to the source electrode DS of the driving thin film transistor DT via the pixel contact hole PH. The pixel electrode ANO may be disposed as being corresponding to the emission area EA.

The first dummy pixel electrode DN1 may be separated from the pixel electrode ANO, and may be disposed at the non-emission area NEA located at the left side of the pixel electrode ANO. The first dummy pixel electrode DN1 may be connected to any one of the data line DL and the switching thin film transistor ST. The first dummy pixel electrode DN1 may be connected to the source electrode SS of the switching thin film transistor ST via the dummy contact hole DH. The second dummy pixel electrode DN2 may be formed by extending the pixel electrode ANO to the non-emission area NEA located at the right side of the pixel electrode ANO. The second dummy pixel electrode DN2 may be extended from the pixel electrode ANO to the second dummy emission area DEA2. That is, the pixel electrode ANO and the second dummy pixel electrode DN2 may be formed as being one thin layer. For the case of the bottom emission type, the pixel electrode ANO, the first dummy pixel electrode DN1 and the second dummy pixel electrode DN2 may be made of a transparent conductive material.

A bank BA may be formed on the pixel electrode ANO, the first dummy pixel electrode DN1 and the second dummy pixel electrode DN2, so the bank BA may define the emission area EA, a first dummy emission area DEA1 and a second dummy emission area DEA2. The bank BA may be disposed as defining the emission area EA corresponding to middle portions of the pixel electrode ANO and the first dummy emission area DEA1 corresponding to middle portions of the first dummy pixel electrode DN1. Further, the bank BA may be disposed as defining the second dummy emission area DEA2 corresponding to middle portions of the second dummy pixel electrode DN2.

Covering the circumferences of the pixel electrode ANO, the first dummy pixel electrode DN1 and the second dummy pixel electrode DN2, the bank BA may define the emission area EA, the first dummy emission area DEA1 and the second dummy emission area DEA2. Covering the connecting portions between the pixel electrode ANO and the second dummy pixel electrode DN2, the bank BA disposed between the pixel electrode ANO and the second dummy pixel electrtode DN2 may distinguish or separate the second dummy emission area DEA2 from the emission area EA.

An emission layer EL may be deposited on the surfaces of the pixel electrode ANO, the first dummy pixel electrode DN1, the second dummy pixel electrode DN2 and the bank BA. The emission layer EL may be deposited on the substrate 110 as covering all pixels P including the blue pixel BP, the white pixel WP and the red pixel RP, and have one-sheet shape continuous over entire surface of the substrate 110.

Even though it is not shown in figures, like FIG. 3, the emission layer EL may have a structure in which a hole functional layer HFL, an organic light emitting layer and an electron functional layer EFL are sequentially stacked. The organic light emitting layer may have a structure in which a first emission layer E1, a first charge generation layer CG1, a second emission layer E2, a second charge generation layer CG2, a third emission layer E3, a third charge generation layer CG3 and a fourth emission layer E4 are sequentially stacked.

A common electrode CAT may be deposited on the emission layer EL. The common electrode CAT may be deposited as covering all pixels P disposed on the substrate 110, and may have one-sheet shape continuously deposited as covering entire surface of the substrate 110. For the bottom emission type, the common electrode CAT may include a metal material having excellent light reflectance.

An encapsulation layer 440 may be deposited on the light emitting element layer 330. The encapsulation layer 440 may have a structure in which a first inorganic layer PA1, an organic layer PCL and a second inorganic layer PA2 may be sequentially stacked.

A light emitting diode OLE may be formed in the emission area EA of the white pixel WP. Further, in the non-emission area NEA, the first dummy light emitting diode DLE1 may be formed at the first dummy emission area DEA1, and the second dummy light emitting diode DLE2 may be formed at the second dummy emission area DEA1. Lights generated from the light emitting diode OLE may be emitted to the outside through the substrate 110. However, lights generated from the first dummy light emitting diode DLE1 and the second dummy light emitting diode DLE2 may be blocked by the light shielding layer LS so that the lights may not be emitted to the outside.

When the light emitting diode disposed in the blue pixel BP is operated, the lateral leakage current may be accumulated at the first dummy light emitting diode DLE1through the emission layer EL. When the light emitting diode OLE of the white pixel WP is operated, the first dummy light emitting diode DLE1 may be operated at the same time. Then, the first dummy light emitting diode DLE1 may emit lights brighter than its original brightness due to the accumulated lateral leakage current. Similarly, when the light emitting diode of the red pixel RP is operated, the lateral leakage current may be accumulated at the second dummy light emitting diode DLE2 through the emission layer EL. When the light emitting diode OLE of the white pixel WP is operated, the second dummy light emitting diode DLE2 may be operated at the same time. Then, the second dummy light emitting diode DLE2 may emit lights brighter than its original brightness due to the accumulated lateral leakage current. Lights generated from the first dummy light emitting diode DLE1 and the second dummy light emitting diode DLE2 may be blocked by the light shielding layer LS so that the lights may not be emitted outside. Accordingly, the lights of the first dummy light emitting diode DLE1 and the second dummy light emitting diode DLE2 that may emit light with a brightness higher than the set brightness of the light emitting diode OLE of the white pixel WP may not be perceived by the user.

Since the first dummy light emitting diode DLE1 may consume the lateral leakage current transmitted from the blue pixel BP to the white pixel WP and the second dummy light emitting diode DLE2 may consume the lateral leakage current transmitted from the red pixel RP to the white pixel WP, the lateral leakage current may not affect the light emitting diode OLE of the white pixel WP.

### Fourth Embodiment

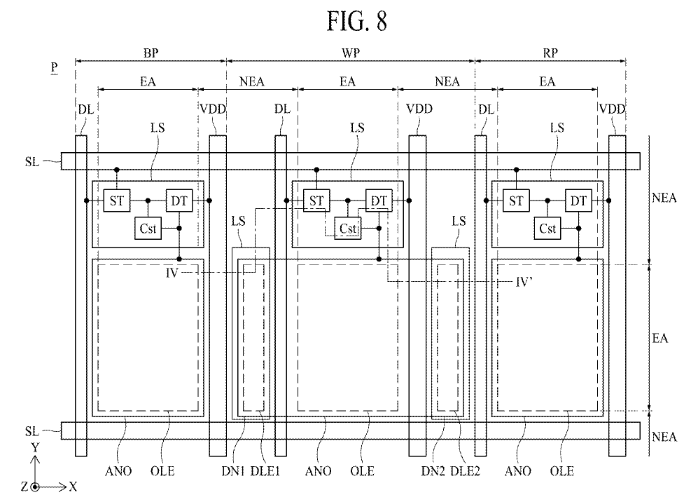

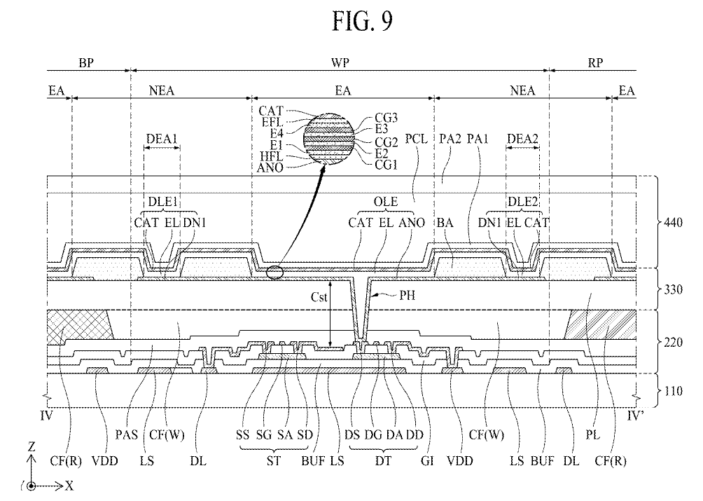

Hereinafter, referring to FIGS. 8 and 9, a detailed structure of a light emitting display device according to a fourth embodiment will be explained. FIG. 8 is an enlarged plan view illustrating a structure of three pixels serially disposed in a light emitting display device according to a fourth embodiment of the present disclosure. FIG. 9 is an enlarged cross-sectional view, cutting along line IV-IV’ in FIG. 8, for illustrating a structure of a light emitting display device according to the fourth embodiment of the present disclosure.

The light emitting display device according to the fourth embodiment may have a structure very similar to that of the third embodiment. The difference may be in the way the first dummy pixel electrode DN1 is connected to the driving element. In following explanation, detailed description of the same elements as in the first embodiment may not be duplicated or briefly described.

Referring to FIG. 8, a blue pixel BP, a white pixel WP and a red pixel RP may be consecutively arranged on the surface of the substrate 110. A green pixel GP may be located at side of the red pixel RP.

Each of the blue pixel BP, the white pixel WP and the red pixel RP may include a driving element which is connected to a scan line SL, a data line DL and a driving current line VDD, and a light emitting element which is connected to the driving element. Each of the blue pixel BP and the red pixel RP may include a switching thin film transistor ST, a driving thin film transistor DT, a light emitting diode OLE and a capacitor Cst.

The white pixel WP may include a switching thin film transistor ST, a driving thin film transistor DT, a light emitting diode OLE, a capacitor Cst, a first dummy light emitting diode DLE1 and a second dummy light emitting diode DLE2. The first dummy light emitting diode DLE1 may be disposed between the white pixel WP and the blue pixel BP. The second dummy light emitting diode DLE2 may be disposed between the white pixel WP and the red pixel RP.

The first dummy light emitting diode DLE1 and the second dummy light emitting diode DLE2 may be connected to the light emitting diode OLE of the white pixel WP. For example, a first dummy pixel electrode DN1 of the first dummy light emitting diode DLE1 may be formed by extending the pixel electrode ANO of the light emitting diode OLE to the non-emitting area NEA positioned on its left side. Further, a second dummy pixel electrode DN2 of the second dummy light emitting diode DLE2 may be formed by extending the pixel electrode ANO of the light emitting diode OLE to the non-emission area NEA positioned on its right side.

In addition, referring to FIG. 9, a cross-sectional structure of the light emitting display device according to the fourth embodiment will be explained. Referring to FIG. 9, in the cross-sectional structure of the light emitting display device according to the fourth embodiment, a substrate 110, a driving element layer 220, a light emitting element layer 330 and an encapsulation layer 440 are sequentially stacked.

A light shielding layer LS, a data line DL and a driving current line VDD may be formed on the substrate 110. A buffer layer BUF may be deposited on the light shielding layer LS, the data line DL and the driving current line VDD as covering entire surface of the substrate 110. A switching thin film transistor ST, a driving thin film transistor DT and a capacitor Cst may be formed on the buffer layer BUF.

A passivation layer PAS may be deposited on the driving elements including the scan line SL, the data line DL, the driving current line VDD, the switching thin film transistor ST and the driving thin film transistor DT, as covering entire surface of the substrate 110. On the passivation layer PAS, the blue pixel BP may include a blue color filter CF(B), and the red pixel RP may include a red color filter CF®. The white pixel WP may include a transparent color filter CF(W).

A light emitting element layer 330 may be deposited on the color filter CF. The light emitting element layer 330 may include a planarization layer PL, a light emitting diode OLE, a first dummy light emitting diode DLE1 and a second dummy light emitting diode DLE2. The light emitting diode OLE may include a pixel electrode ANO, an emission layer EL and a common electrode CAT. The first dummy light emitting diode DLE1 may include a first dummy pixel electrode DN1, the emission layer EL and the common electrode CAT. The second dummy light emitting diode DLE2 may include a second dummy pixel electrode DN2, the emission layer EL and the common electrode CAT.

The pixel electrode ANO, the first dummy pixel electrode DN1 and the second dummy pixel electrode DN2 may be formed on the planarization layer PL. The first dummy pixel electrode DN1 and the second dummy pixel electrode DN2 may be fully overlapped with the light shielding layer LS.

The first dummy pixel electrode DN1 may be formed by extending the pixel electrode ANO to the non-emission area NEA located at the left side of the pixel electrode ANO. The first dummy pixel electrode DN1 may be extended from the pixel electrode ANO to the first dummy emission area DEA1. The second dummy pixel electrode DN2 may be formed by extending the pixel electrode ANO to the non-emission area NEA located at the right side of the pixel electrode ANO. The second dummy pixel electrode DN2 may be extended from the pixel electrode ANO to the second dummy emission area DEA2. That is, the pixel electrode ANO, the first dummy pixel electrode DN1 and the second dummy pixel electrode DN2 may be formed as being one thin layer. The first dummy pixel electrode DN1 may be connected to the source electrode DS of the driving thin film transistor DT via the pixel contact hole PH.

A bank BA may be formed on the pixel electrode ANO, the first dummy pixel electrode DN1 and the second dummy pixel electrode DN2, so the bank BA may define the emission area EA, a first dummy emission area DEA1 and a second dummy emission area DEA2. Covering the circumferences of the pixel electrode ANO, the first dummy pixel electrode DN1 and the second dummy pixel electrode DN2, the bank BA may define the emission area EA, the first dummy emission area DEA1 and the second dummy emission area DEA2. Further, covering the connecting portions between the pixel electrode ANO and the first dummy pixel electrode DN1, the bank BA disposed between the pixel electrode ANO and the first dummy pixel electrtode DN1 may distinguish or separate the first dummy emission area DEA1 from the emission area EA. Similarly, covering the connecting portions between the pixel electrode ANO and the second dummy pixel electrode DN2, the bank BA disposed between the pixel electrode ANO and the second dummy pixel electrode DN2 may distinguish or separate the second dummy emission area DEA2 from the emission area EA.

An emission layer EL may be deposited on the surfaces of the pixel electrode ANO, the first dummy pixel electrode DN1, the second dummy pixel electrode DN2 and the bank BA. A common electrode CAT may be deposited on the emission layer EL. Each of the emission layer EL and the common electrode CAT may be deposited as covering all pixels P on the surface of the substrate 110, and have one-sheet layer continuous over entire surface of the substrate 110. An encapsulation layer 440 may be deposited on the light emitting element layer 330.

A light emitting diode OLE may be formed in the emission area EA of the pixel P. Further, in the non-emission area NEA, the first dummy light emitting diode DLE1 may be formed at the first dummy emission area DEA1, and the second dummy light emitting diode DLE2 may be formed at the second dummy emission area DEA1. Lights generated from the light emitting diode OLE may be emitted to the outside through the substrate 110. However, lights generated from the first dummy light emitting diode DLE1 and the second dummy light emitting diode DLE2 may be blocked by the light shielding layer LS so that the lights may not be emitted to the outside.

Since the first dummy light emitting diode DLE1 may consume the lateral leakage current transmitted from the blue pixel BP to the white pixel WP and the second dummy light emitting diode DLE2 may consume the lateral leakage current transmitted from the red pixel RP to the white pixel WP, the lateral leakage current may not affect the light emitting diode OLE of the white pixel WP.

In the above-mentioned embodiments described referring to the figures, the descriptions are focused on the structure of the bottom emission type in which the color filter CF may be disposed between the light emitting diode OLE and the substrate 110. However, the important features of the present disclosure are not limited to the bottom emission type. For example, the features of the present disclosure may be applied to the top emission type in which the color filter CF is disposed over the light emitting diode OLE. For example, the color filter CF may be disposed on the encapsulation layer 440. For another example, a glass substrate may be used for an encapsulation substrate, and the glass substrate may be joined with the substrate 110 having the light emitting diode OLE. In this case, the color filter CF may be disposed under the glass encapsulation substrate.

Further, in the above embodiments, the emission layer EL may be described as having a structure in which a first emission layer E1, a second emission layer E2, a third emission layer E3 and a fourth emission layer E4 are sequentially stacked. However, it is not limited thereto. Three or two emission layers may be stacked, or more than 4 emission layers may be stacked. Each of the stacked emission layers, i.e., four emission layers E1, E2, E3 and E4, may include organic light emitting material that emits any one of the red, green and blue color lights. At least two layers of the four emission layers E1, E2, E3 and E4 may include an organic light emitting material generating blue lights.

In the above embodiments, descriptions are focused on the cases of a thin film transistor having a top gate structure in which a gate electrode is positioned on top of the semiconductor layer with a gate insulating layer there-between. However, it is not limited thereto. The thin film transistors may include a bottom gate structure in which the gate electrode is located under the semiconductor layer. Otherwise, the thin film transistor may include a double gate structure in which two gate electrodes are disposed over and under the semiconductor layer, respectively.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment may be implemented in combination or modification with respect to other example embodiments by those skilled in the art to which this disclosure is directed. Accordingly, such combinations and modifications should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the detailed description.

What is claimed is:

1. A light emitting display device comprising:
a plurality of pixels on a substrate;
a driving element layer on the substrate;
a pixel electrode disposed in each pixel of the plurality of pixels on the driving element layer;
a dummy pixel electrode disposed at least one side of the pixel electrode;
a bank defining an emission area at the pixel electrode and a dummy emission area at the dummy pixel electrode;
an emission layer continuously deposited on the pixel electrode, the dummy pixel electrode and the bank;
a common electrode on the emission layer; and
a light shielding layer overlapping the dummy pixel electrode except the pixel electrode,
wherein the pixel electrode and the dummy pixel electrode is connected to a driving element disposed in the driving element layer.

2. The light emitting display device according to claim 1, further comprising:
a color filter disposed between the driving element layer and the pixel electrode; and
a planarization layer between the color filter and the pixel electrode,
wherein the light shielding layer is disposed between the substrate and the driving element layer.

3. The light emitting display device according to claim 1, wherein the driving element layer includes:
a data line;
a driving current line parallel to the data line;
a scan line intersecting the data line and the driving current line;
a switching thin film transistor between the data line and the scan line; and
a driving thin film transistor between the switching thin film transistor and the driving current line,
wherein the pixel electrode is connected to the driving thin film transistor, and
wherein the dummy pixel electrode is connected any one of the data line, the switching thin film transistor and the driving thin film transistor,
wherein a compensation light emitting diode is disposed as corresponding to a light shielding layer.

4. The light emitting display device according to claim 3, wherein the dummy pixel electrode is separated from the pixel electrode, and connected to a source electrode of the switching thin film transistor, and
wherein the bank covers circumferences of the pixel electrode and the dummy pixel electrode.

5. The light emitting display device according to claim 3, wherein the dummy pixel electrode is disposed at the dummy emission area by extended from the pixel electrode, and
wherein the bank covers circumferences of the pixel electrode and the dummy pixel electrode, and is disposed between the pixel electrode and the dummy pixel electrode.

6. The light emitting display device according to claim 1, wherein the plurality of pixels includes a blue pixel, a white pixel and a red pixel consequently arrayed,
wherein the dummy pixel electrode of the white pixel includes:
a first dummy pixel electrode disposed at a first dummy emission area between the white pixel and the blue pixel; and
a second dummy pixel electrode disposed at a second dummy emission area between the white pixel and the red pixel.

7. The light emitting display device according to claim 6, wherein the driving element layer includes:
a data line, a driving current line parallel to the data line and a scan line crossing to the data line and the driving current line in each of the plurality of pixels;
a switching thin film transistor between the data line and the scan line; and
a driving thin film transistor between the switching thin film transistor and the driving current line,
wherein the pixel electrode of the white pixel is connected to the driving thin film transistor, and
wherein the first dummy pixel electrode and the second dummy pixel electrode of the white pixel is connected to any one of the data line, the switching thin film transistor and the driving thin film transistor.

8. The light emitting display device according to claim 7, wherein the first dummy pixel electrode is located in the first dummy emission area and connected to any one of the data line and the switching thin film transistor,
wherein the second dummy pixel electrode is extended from the pixel electrode to the second dummy emission area, and
wherein the bank covers circumferences of the pixel electrode, the first dummy pixel electrode and the second dummy pixel electrode in the white pixel and is disposed between the pixel electrode and the second dummy pixel electrode of the white pixel.

9. The light emitting display device according to claim 7, wherein the first dummy pixel electrode is extended from the pixel electrode to the first dummy emission area,
wherein the second dummy pixel electrode is extended from the pixel electrode to the second dummy emission area, and
wherein the bank covers circumferences of the pixel electrode, the first dummy pixel electrode and the second dummy pixel electrode, and is disposed between the pixel electrode and the first dummy pixel electrode and between the pixel electrode and the second dummy pixel electrode.

10. The light emitting display device according to claim 1, wherein the emission layer includes:
a first emission layer on the pixel electrode, the dummy pixel electrode and the bank;
a first charge generation layer on the first emission layer;
a second emission layer on the first charge generation layer;
a second charge generation layer on the second emission layer;
a third emission layer on the second charge generation layer;
a third charge generation layer on the third emission layer; and
a fourth emission layer on the third charge generation layer.

11. The light emitting display device according to claim 10, wherein the pixel electrode includes:
a hole functional layer on the pixel electrode, the dummy pixel electrode and the bank and under the first emission layer; and
an electron functional layer between the fourth emission layer and the common electrode.

12. The light emitting display device according to claim 11, wherein the first emission layer provides a red light,
wherein the second emission layer provides a first blue light,
wherein the third emission layer provides a green light, and
wherein the fourth emission layer provides a second blue light.

13. The light emitting display device according to claim 1, wherein the emission area is a first region where lights provided from the emission layer emit to outside through the substrate, and
wherein the dummy emission area is a second region where lights provided from the emission layer is blocked by the light shielding layer not to emit to outside.
